(19) United States
(12) Patent Application Publication
(10) Pub. No.: US 2015/0035094 A1
(43) Pub. Date: Feb. 5, 2015

(54) MICROPHONE ASSEMBLY HAVING AT LEAST TWO MEMS MICROPHONE COMPONENTS

(71) Applicants: Franz LAERMER, Weil Der Stadt (DE); Ricardo EHRENPFORDT, Korntal-Muenchingen (DE); Jochen ZOELLIN, Muellheim (DE); Bill SCOTT, Burnsville, MN (US); Jeff BERRYMAN, Flesherton (CA)

(72) Inventors: Franz LAERMER, Weil Der Stadt (DE); Ricardo EHRENPFORDT, Korntal-Muenchingen (DE); Jochen ZOELLIN, Muellheim (DE); Bill SCOTT, Burnsville, MN (US); Jeff BERRYMAN, Flesherton (CA)

(73) Assignee: ROBERT BOSCH GMBH, Stuttgart (DE)

(21) Appl. No.: 14/446,066

(22) Filed: Jul. 29, 2014

(30) Foreign Application Priority Data
Jul. 30, 2013 (DE) 10 2013 214 823.2

(51) Int. Cl. B81B 3/00; H04R 23/00

(52) U.S. Cl. CPC B81B 3/0021; H04R 23/00; H04R 2201/003; B81B 2201/0257
USPC 257/416

(57) ABSTRACT

A microphone assembly includes two MEMS components each having a micromechanical microphone structure, each microphone structure having: a diaphragm configured to be deflected by sound pressure and provided with at least one diaphragm electrode of a capacitor system; and a stationary acoustically permeable counter-element that acts as bearer for at least one counter-electrode of the capacitor system. The microphone assembly is configured such that under the action of sound the spacing between the diaphragm and the counter-element of the two microphone structures changes in opposite directions.

### BACKGROUND OF THE INVENTION

1. Field of the Invention

The present invention relates to a microphone assembly having at least one first and at least one second MEMS component, each having at least one micromechanical microphone structure, and each of these microphone structures has a diaphragm that can be deflected by sound pressure and that is provided with at least one diaphragm electrode of a capacitor system, and a stationary, acoustically permeable counter-element that acts as a bearer for at least one counter-electrode of the capacitor system.

2. Description of the Related Art

Microphone assemblies of the type under consideration here having capacitive MEMS microphone components are known in practice. The sound pressure, or the diaphragm deflection caused thereby, causes a change in the capacitance between a deflectable electrode on the acoustically active diaphragm and a largely rigid counter-electrode on the acoustically permeable counter-element of the microphone structure. For signal acquisition, a pre-voltage is applied to the microphone capacitor. A very high pre-voltage resistance ensures that the charge of the microphone capacitor remains constant. In this way, changes in capacitance of the microphone capacitor can be acquired as changes in voltage. This type of signal acquisition is extremely sensitive, low-noise, and temperature-stable, and thus contributes to the good performance of MEMS microphone components.

However, it is problematic that the relation between the diaphragm deflection and sound pressure in MEMS microphone components is not always linear. A reason for this is that the spring action or resetting force of the diaphragm decreases over time. This is mainly due to the fact that in the operating state the diaphragm is permanently mechanically pre-stressed. Moreover, the diaphragm is deflected in planar-parallel fashion only in a limited sound pressure range. In particular in the case of high sound pressures, there additionally occurs a warping of the diaphragm, causing mechanical stresses inside the diaphragm and resulting in stiffening of the diaphragm. These effects increase with the degree of deflection or warping of the diaphragm, and also contribute to the non-linearity of the relation between the sound pressure and the diaphragm deflection.

In any case, the effects described above cause harmonic overtones in the measured acoustic spectrum, which together with intermodulation effects impair the sound quality of the microphone.

### BRIEF SUMMARY OF THE INVENTION

The present invention proposes measures by which the non-linear influence that the microphone structure has on the capacitive signal acquisition can be easily and efficiently reduced.

For this purpose, the microphone assembly according to the present invention has at least two MEMS components having a microphone structure for capacitive signal acquisition, mounted in such a way that under the action of sound the spacing between the diaphragm and the counter-element of the two microphone structures changes in opposite directions.

Thus, here the two microphone structures are configured in a push-pull configuration so that the sound pressure causes, in each microphone structure, an enlargement of the electrode spacing of the capacitor system, while the electrode spacing in the capacitor system of the other microphone structure become smaller. Accordingly, the output signals of the two MEMS microphone components are phase-shifted by 180°. The first harmonic oscillation of the output signals corresponds in each case to the useful signal. Due to the phase shift, these have different signs. The non-linear portions of the two output signals correspond to the harmonic overtones, which, despite the phase shift, have the same sign. Correspondingly, these portions can easily be eliminated, or at least significantly reduced, through subtraction of the two output signals, while the useful signal can be doubled, or at least significantly amplified. In this way, using MEMS components having a comparatively simple microphone structure, a microphone assembly can be realized having a very high sound quality.

In principle, there are many different possibilities for the realization of the assembly design according to the present invention, not limited to MEMS components having a particular microphone structure. Frequently, the microphone structure of an MEMS component is realized in a layer construction on a substrate, and includes an acoustically active diaphragm having a microphone electrode that spans an opening in the substrate rear side and a stationary acoustically permeable counter-element having ventilation openings as a bearer for a counter-electrode of the microphone capacitor system. The counter-element having the counter-electrode can be fashioned over, or also under, the diaphragm in the layer construction. The diaphragm can be connected circumferentially, or also only via one or more spring elements, to the layer construction of the MEMS component. It can be connected over the substrate or also over the counter-element in the layer construction. The action of sound on the diaphragm can take place via the rear-side opening in the substrate, or also via the ventilation openings in the counter-element. The concrete realization of the MEMS components, and in particular of the microphone structures, is primarily a function of the technical requirements made on the microphone assembly, the available manufacturing processes, and the available budget for manufacturing.

Independently of the concrete design of the MEMS components, in the context of a microphone assembly according to the present invention MEMS components are preferably used whose microphone structures are essentially identical in construction, because in this case the non-linear influences of the microphone structures on the signal acquisition can be very largely eliminated through simple subtraction of the output signals.

In a simplest specific embodiment of the present invention, the two MEMS components of a microphone assembly are mounted in such a way that the deflection of the diaphragms caused by sound pressure takes place independently of one another. For this purpose, two identically designed MEMS components can easily be mounted on different sides of a rigid bearer, so that their microphone structures are oriented in opposite directions. Given the use of a flexible bearer, the two MEMS components can also be mounted on the same side of the bearer. In this case, the two microphone structures can easily be oriented in different directions through twisting or folding of the bearer.

A better suppression of the non-linear influences of the microphone structures on the signal acquisition can be achieved if the diaphragms of the two microphone structures are mechanically or acoustically coupled. For this purpose, in a preferred specific embodiment of the present invention the two MEMS components are mounted one over the other, either directly or with an intermediate bearer, so that the diaphragms of the two microphone structures are connected to one another via an air volume.

As an intermediate bearer, a rigid bearer, such as a circuit board, having a through-opening can be used. In the case of microphone structures having identical design, such a bearer is equipped on both sides by mounting the two MEMS components opposite one another on the front side and on the rear side of the bearer over the through-opening. The two microphone structures are then oriented in opposite directions, and the diaphragms of the two microphone structures are mechanically coupled via an air volume that extends through the through-opening in the bearer.

Given the use of a flexible bearer, two identically designed MEMS components can also be mounted on the same side of the bearer, each over a through-opening in the bearer. The two microphone structures can then easily be positioned one over the other, and oriented in opposite directions, by folding the bearer, so that the diaphragms of the two microphone structures are coupled via an air volume that extends through the two through-openings in the bearer, positioned so as to be aligned with one another.

Such an intermediate bearer is advantageously a part of an assembly housing that encloses a rear-side volume for the microphone function.

The two MEMS components can however also be connected directly to one another so that they form a chip stack in which the microphone structures are oriented in opposite directions and an air volume is enclosed between the two diaphragms. This variant design proves advantageous in many respects. For one, in this way a very good mechanical coupling can be achieved between the two microphone structures, because this coupling is stronger the smaller the air volume between the two diaphragms is. This has a positive effect on the sound quality of the microphone assembly. Furthermore, the situation of the two MEMS components in a chip stack or wafer level package is particularly space-saving, and thus corresponds to the general trend towards miniaturization in MEMS assemblies. Such a chip stack can easily be mounted on a bearer or at least partly in an opening of a bearer that is part of an assembly housing having a rear side volume for the microphone function.

Finally, it is also to be noted that the assembly design according to the present invention also provides the possibility of realizing microphone assemblies having a grid system of first and second MEMS components having a microphone structure. These microphone assemblies can for example be used as directional microphones.

### BRIEF DESCRIPTION OF THE DRAWINGS

FIG. 1 shows a schematic sectional representation of an assembly 100 according to the present invention having two acoustically coupled MEMS microphone components that are mounted on the front side and on the rear side of a circuit board.

FIGS. 2a-2c illustrate a variant assembly for the MEMS components of assembly 100 on the basis of schematic sectional representations.

FIGS. 3a and 3b each show a schematic sectional representation of a MEMS component system according to the present invention in the form of a chip stack 301 or 302.

FIG. 4 shows a schematic sectional representation of an assembled chip stack having a grid configuration of acoustically coupled first and second MEMS microphone structures.

FIG. 5 shows a schematic sectional representation of a system 500 according to the present invention of two acoustically decoupled MEMS microphone components on the two sides of a circuit board.

FIGS. 6a and 6b illustrate a variant assembly for the MEMS components of system 500 on the basis of schematic sectional representations.

### DETAILED DESCRIPTION OF THE INVENTION

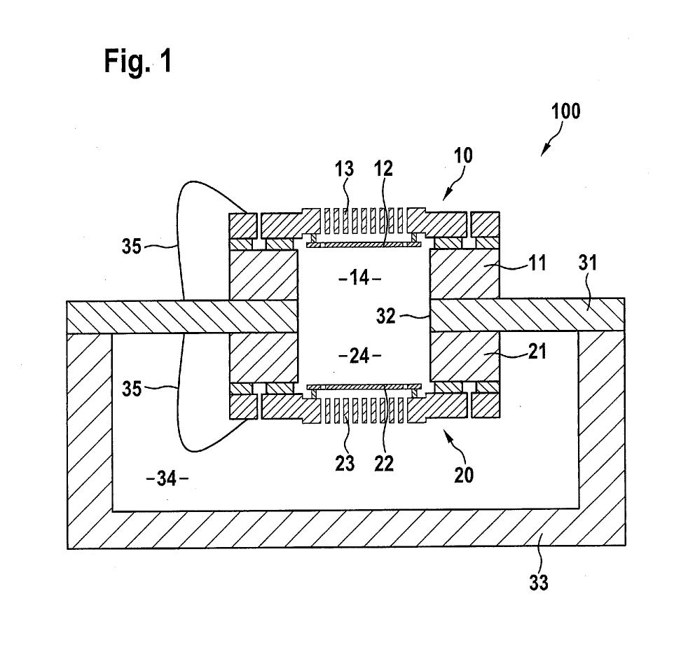

Microphone assembly 100 shown in FIG. 1 includes two MEMS components 10, 20 each having a micromechanical microphone structure, which in the exemplary embodiment described here are essentially identical in their construction. The two microphone structures are fashioned in a layer construction over a substrate 11, or 21, and include a deflectable acoustically active diaphragm 12, or 22, provided with a diaphragm electrode of a capacitor system, and a stationary acoustically permeable counter-element 13, or 23, that acts as bearer for a counter-electrode of the capacitor system. The diaphragm electrode and counter-electrode are not shown in detail here for reasons of clarity. In the present exemplary embodiment, both diaphragms 12 and 22 are fashioned in the layer construction under the associated counter-element 13 or 23, and are connected to the respective layer construction via this counter-element 13 or 23. Diaphragm 12 or 22 and counter-element 13 or 23 span an opening 14 or 24 in the respective substrate rear side.

Microphone component 100 also includes a bearer 31 for mounting the two MEMS components 10 and 20. This is a circuit board 31 having a through-opening 32. The one MEMS component 10 is mounted on the front side of circuit board 31, and the other MEMS component 20 is mounted on the rear side of circuit board 31, in each case with rear-side opening 14 or 24 over through-opening 32. In this way, the microphone structures of the two MEMS components 10, 20 are oriented in opposite directions. In addition, via the air cushion in the area of through-opening 32 there exists an acoustic coupling between the two diaphragms 12 and 22. Together with a cover part 33, circuit board 31 encloses a rear-side volume 34 for the microphone function. For this purpose, cover part 33 was mounted on circuit board 31 over MEMS component 20. Here, the action of sound takes place via counter-element 13 onto diaphragm 12 of MEMS component 10. Via the air volume in the region of through-opening 32, the sound pressure is also transmitted onto diaphragm 22 of MEMS component 20. Because the microphone structures of the two MEMS components 10 and 20 are however oriented in opposite directions, when there is the action of sound the spacings between diaphragm 12 or 22 and counter-element 13 or 23 of the two microphone structures also change in opposite directions. These changes in spacing are acquired using the respective capacitor system and are supplied to a signal processing. This can for example be implemented in an ASIC component that is also mounted on the circuit board. In any case, the microphone structures of the two MEMS components are also connected electrically to circuit board 31, indicated here by bonding wires 35.

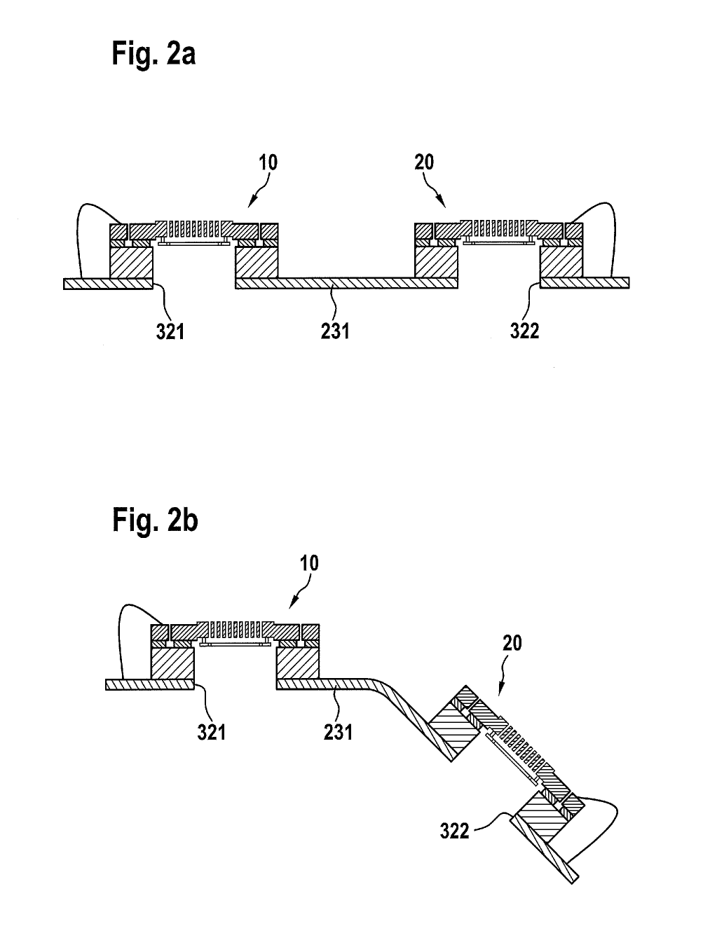

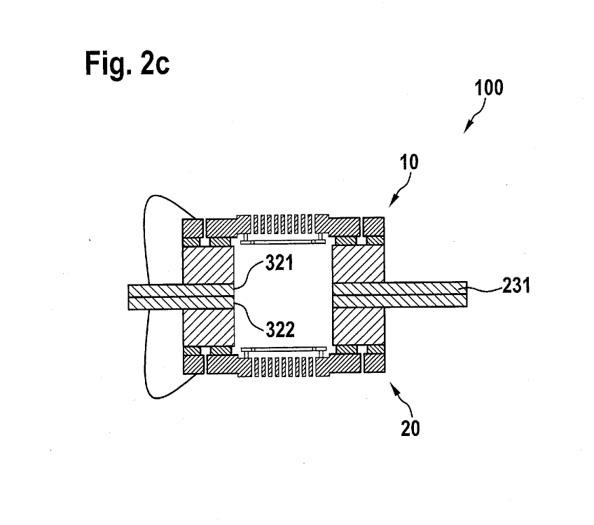

The equipping, described in connection with FIG. 1, of a bearer on both sides with MEMS and, if warranted, also ASIC components, and the electrical contacting thereof via bonding wires, is relatively costly. A simpler and also lower-cost possible realization for the design of such a microphone assembly is shown in FIGS. 2a through 2c. Here, instead of a rigid bearer such as a circuit board, a rigid-flexible bearer 231, i.e. a rigid bearer having a defined bending point, is used, made for example of a polyimide. As can be seen from FIG. 2a, in this case the two MEMS components 10 and 20 are mounted with the substrate rear side on the front side of bearer 231, in each case via a separate through-opening 321 and 322 in bearer 231. The electrical contacting of the microphone structures takes place here as well using bonding wires 35 that are each guided from the component front side to the front side of bearer 231.

In a further assembly step, bearer 231 is folded in order to situate the two through-openings 321 and 322 one over the other, i.e. aligned with one another, as indicated in FIG. 2b.

FIG. 2c shows equipped bearer 231 in the folded-together state. Because, except for the type of bearer, this design corresponds to the design of component 100, reference is made to the description of FIG. 1 for the explanation of the rest of the assembly components.

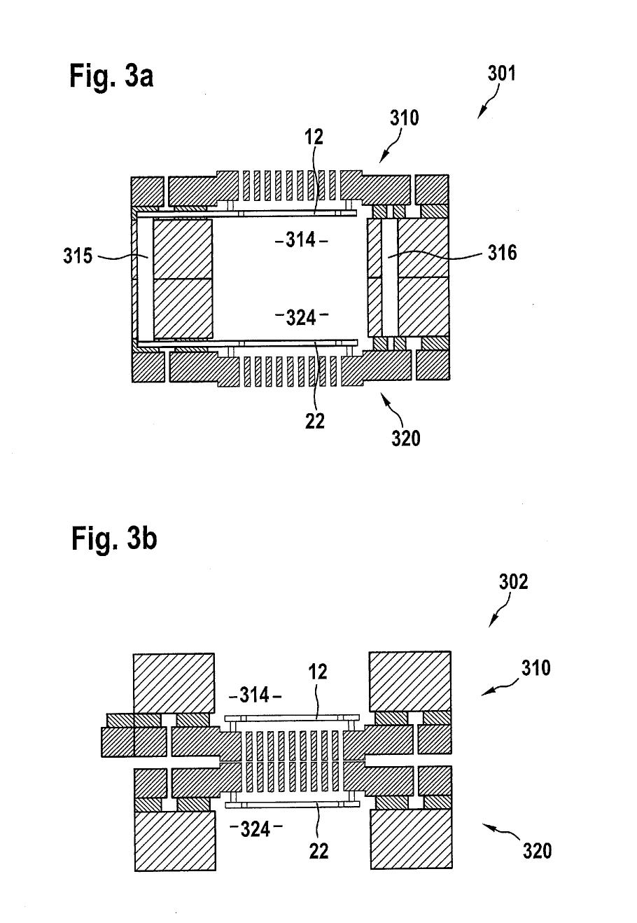

The assembly design according to the present invention provides that the microphone structures of the two MEMS components are oriented in opposite directions inside the microphone assembly, i.e. in such a way that under the action of sound the spacing between the diaphragm and counter-element of the two microphone structures changes in opposite directions. In a particularly compact and space-saving constructive embodiment, this configuration is realized not with the aid of a bearer on which the MEMS components are mounted but rather through a wafer level assembly in which the MEMS components are mounted directly one over the other. FIGS. 3a and 3b show such chip stacks 301 and 302. The microphone structures of the two MEMS components 310 and 320 are essentially identical in their construction to the microphone structures of MEMS components 10 and 20 shown in FIG. 1, so that reference is made to the explanations relating to FIG. 1 in this regard.

In the case of FIG. 3a—chip stack 301—the two MEMS components 310 and 320 are connected at the rear side, so that the openings in the substrate rear side are aligned with one another. Here, the two microphone structures are acoustically coupled via the air volume 314 enclosed in this way between the two diaphragms 12 and 22. Through rear-side thinning of MEMS components 310 and 320 before assembly, this air volume 314, 324 can be made smaller in order to improve the mechanical coupling between the two microphone structures.

Depending on how chip stack 301 is mounted inside an assembly housing, the introduction of sound takes place via counter-element 13 or 23 of MEMS component 310 or 320.

The electrical connection between the microphone structures of the two MEMS components 310 and 320, as well as the overall electrical contacting of chip stack 301, here takes place through vias 315, 316, each fashioned laterally next to the microphone structure of MEMS components 310 and 320 and aligned with one another. Thus, at the left next to the microphone structures there is situated a via 315 for the electrical contacting of diaphragms 12 and 22, and at the right next to the microphone structures there is situated a via 316 for the electrical contacting of counter-elements 13 and 23.

Alternatively, the one MEMS component 320 of chip stack 301 can also be electrically contacted during assembly onto a circuit board in flip-chip technology, and the other MEMS component 310 can be connected to the circuit board using bonding wires.

In the case of FIG. 3b—chip stack 302—the two MEMS components 310 and 320 are connected to one another “face-to-face,” i.e. via the two counter-elements 13 and 23 of the two microphone structures. The two microphone structures are here acoustically coupled via the air volume in the region of counter-elements 13, 23 between the two diaphragms 12 and 22. Depending on how chip stack 302 is mounted inside an assembly housing, the introduction of sound takes place via rear-side opening 314 or 324 in the substrate of MEMS component 310 or 320.

Through wafer level assembly, chip stacks having a grid configuration of first and second acoustically coupled MEMS microphone structures can be produced very easily and at low cost, as described above in connection with FIGS. 3a and 3b. As is shown in FIG. 1, such a microphone array can then be mounted on a bearer of the assembly housing and electrically contacted.

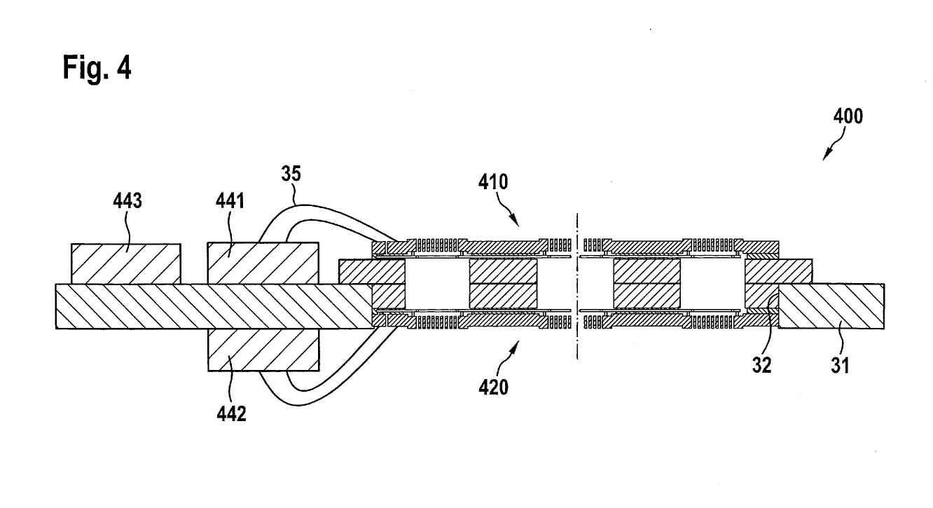

FIG. 4 shows a particularly space-saving assembly variant for such a microphone array. Chip stack 400 includes a large number of microphone structure pairs configured in a grid, indicated by the central perpendicular broken line. The microphone structure pairs are constructed in the manner of chip stack 301 of FIG. 3a, and are therefore not discussed here in detail. The microphone structures of the two chips 410 and 420 can be contacted individually through wire bonds, or can be electrically coupled via a redistribution layer (not shown here in detail), so that the microphone structures of a chip 410 or 420 can be contacted in common. Lower chip 420 of chip stack 400 is at least partly fitted into a through-opening 32 in a circuit board 31, while upper chip 410 extends laterally past through-opening 32, so that chip stack 400 is seated with upper chip 410 on the upper side of circuit board 31.

Each of the two chips 410 and 420 is connected, via bonding wires 35, to a separate pre-amplifier 441 or 442 in order to improve the signal quality. Preamplifiers 441 and 442 are here mounted on the upper side or underside of circuit board 31 and are electrically connected via circuit board 31 to an evaluation ASIC 443. The output signals of preamplifiers 441 and 442 are subtracted, using ASICs 443, in order to amplify the linear portions of the two output signals and to attenuate the non-linear portions of the two output signals.

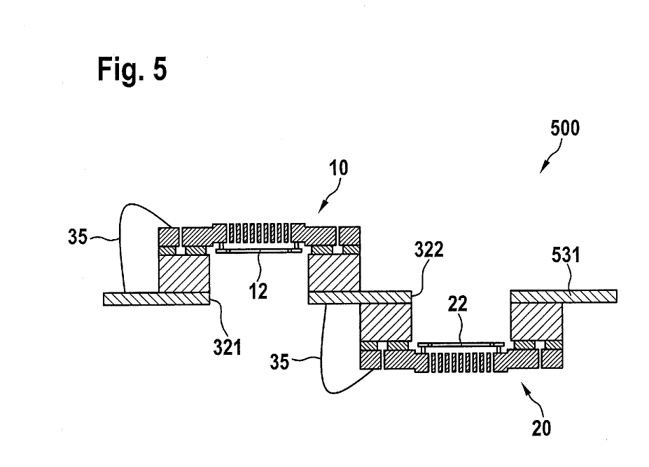

In all exemplary embodiments described above, the two MEMS components of a microphone assembly according to the present invention have been configured in such a way that their microphone structures are not only oriented in different directions, but are also acoustically coupled. However, the assembly design according to the present invention also includes embodiments in which the microphone structures are not acoustically coupled. Such a system 500 of two MEMS components 10 and 20 having a microphone structure is shown in FIG. 5. Because the two MEMS components 10 and 20 are essentially identical in their construction to MEMS components 10 and 20 shown in FIG. 1, reference is made in this regard to the explanations relating to FIG. 1. Here, the two MEMS components 10 and 20 are mounted independently of one another on the front side and on the rear side of a circuit board 531, each with rear-side opening 14 or 24 positioned over a separate through-opening 321 or 322 in circuit board 531. As a result, the microphone structures are oriented in opposite directions. When the sound pressure in the one microphone structure causes an enlargement of the spacing between the diaphragm and the counter-element, the same sound pressure, independently of the diaphragm movement of the first microphone structure, causes in the other microphone structure a reduction of the spacing between the diaphragm and the counter-element. In this variant design, the two MEMS microphone components 10 and 20 have similar sensitivity and are excited in the same manner by sound pressure.

Of course, here as well MEMS components having a large number of microphone structures, so-called microphone arrays, can also be used in an assembly.

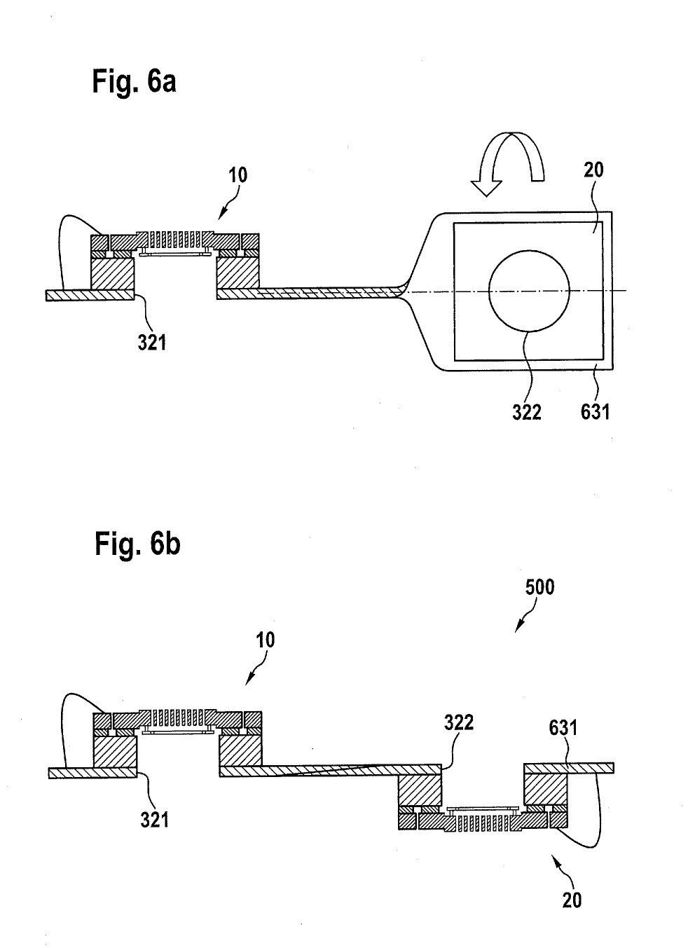

The equipping on both sides of a bearer with MEMS components, described in connection with FIG. 5, and the electrical contacting thereof via bonding wires is relatively costly. A simpler and also lower-cost possible realization for such a MEMS system is shown in FIGS. 6a and 6b. Here, instead of a rigid bearer such as a circuit board, a flexible, bendable bearer 631 is used, for example made of a polyimide. The two MEMS components 10 and 20 are mounted with the substrate rear side on the front side of bearer 631, in each case over a separate through-opening 321 and 322 in bearer 631. The electrical contacting of the microphone structures here takes place using bonding wires 35 that are each routed from the component front side to the front side of bearer 631. In a further assembly step, bearer 631 is then twisted on itself by 180° in order to orient the two MEMS components 10 and 20 in opposite directions, as indicated in FIG. 6a.

FIG. 6b shows equipped bearer 631 in the twisted state. Except for the realization of the bearer, this design corresponds to that of MEMS system 500 shown in FIG. 5.

What is claimed is:

1. A microphone assembly, comprising:
at least one first MEMS component and at least one second MEMS component each having at least one micromechanical microphone structure;
wherein each microphone structure has (i) a diaphragm configured to be deflected by sound pressure and provided with at least one diaphragm electrode of a capacitor system, and (ii) a stationary acoustically permeable counter-element acting as a bearer for at least one counter-electrode of the capacitor system, and wherein the two MEMS components are arranged such that, under the influence of the sound pressure, the respective spacing between the diaphragm and the counter-element of the two microphone structures changes in opposite directions.

2. The microphone assembly as recited in claim 1, wherein the microphone structures of the two MEMS components are essentially identical.

3. The microphone assembly as recited in claim 1, wherein the two MEMS components are arranged such that deflections of the diaphragms of the two MEMS components caused by the sound pressure take place independently of one another.

4. The microphone assembly as recited in claim 3, wherein the two MEMS components are mounted on different sides of a rigid bearer such that the two microphone structures are oriented in opposite directions.

5. The microphone assembly as recited in claim 3, wherein the two MEMS components are mounted on the same side of a flexible bearer which is one of twisted or folded, whereby the two microphone structures are oriented in opposite directions.

6. The microphone assembly as recited in claim 1, wherein the two MEMS components are situated one over the other in such a way that the diaphragms of the two microphone structures are mechanically coupled via an air volume between the two diaphragms.

7. The microphone assembly as recited in claim 6, wherein the two MEMS components are mounted on two sides of a bearer over a through-opening in the bearer in such a way that (i) the two microphone structures are oriented in opposite directions, and (ii) the diaphragms of the two microphone structures are mechanically coupled via an air volume which extends over the through-opening.

8. The microphone assembly as recited in claim 6, wherein the two MEMS components are each mounted on the same side of a flexible bearer over respective through-opening in the bearer, the flexible bearer being folded such that (i) the two microphone structures are situated one over the other and oriented in opposite directions, and (ii) the through-openings in the bearer being aligned with one another, and wherein the diaphragms of the two microphone structures are mechanically coupled via an air volume in the region of the through-openings in the bearer.

9. The microphone assembly as recited in claim 5, wherein the bearer is a part of an assembly housing which encloses a rear-side volume for providing microphone function.

10. The microphone assembly as recited in claim 6, wherein the two MEMS components are mounted directly on one another in such a way that (i) the microphone structures are oriented in opposite directions, and (ii) the diaphragms of the two microphone structures are mechanically coupled via an air volume between the two diaphragms.

11. The microphone assembly as recited in claim 10, wherein the two MEMS components are mounted as a chip stack one of (i) on a bearer or (ii) at least partly in an opening of the bearer, and wherein the bearer is part of an assembly housing enclosing a rear-side volume for providing microphone function.

12. The microphone assembly as recited in claim 6, wherein multiple first MEMS components and multiple second MEMS microphone components are provided such that multiple micromechanical microphone structures are configured in a grid.
